(19) United States
(12) Patent Application Publication
(10) Pub. No.: US 2012/0063246 A1
(43) Pub. Date: Mar. 15, 2012

(54) MEMORY CONTROLLER, MEMORY SYSTEM INCLUDING THE SAME, AND CONTROL METHOD OF MEMORY DEVICE

(75) Inventor: Eiji SUZUKI, Yamanashi (JP)

(73) Assignee: NEC COMPUTERTECHNO, LTD., Kofu-shi (JP)

(21) Appl. No.: 13/228,002

(22) Filed: Sep. 8, 2011

(30) Foreign Application Priority Data
Sep. 13, 2010 (JP) 2010-204114

(51) Int. Cl. G11C 8/18

(52) U.S. Cl. 365/193

(57) ABSTRACT

One aspect of the present invention is a memory controller which controls a memory device including two or more memory access units and includes a data control circuit and an adjusting circuit that performs at least one of a first processing and a second processing. In the first processing, a timing of the write strobe signal generated by the data control circuit in a write operation is adjusted for each memory access unit and a write strobe adjusting signal specifying a timing for each memory access unit to load write data is generated, and in the second processing, a timing of the read strobe signal generated by the memory device in a read operation is adjusted for each memory access unit and a read strobe adjusting signal specifying a timing for the data control unit to read data read out from each memory access unit is generated.

### INCORPORATION BY REFERENCE

This application is based upon and claims the benefit of priority from Japanese patent application No. 2010-204114, filed on Sep. 13, 2010, the disclosure of which is incorporated herein in its entirety by reference.

### BACKGROUND

1. Field of the Invention

The invention relates to a memory controller, a memory system including the same, and a control method of a memory device.

2. Description of Related Art

A memory system has been previously known in which an access unit for write/read operation to/from a memory device is configured as a rank. The rank includes a plurality of memory elements. In the memory system, a memory controller is connected to the plurality of memory elements of the rank by wires.

As related art pertaining to the present invention, there are disclosed Japanese Unexamined Patent Application Publication Nos. 2003-60488, 2007-12245, and 2009-217344. Japanese Unexamined Patent Application Publication No. 2003-60488 disclosed a circuit in which a plurality of delay circuits are adjusted for each transmission path to transmit a signal. The plurality of delay circuits are switched by a transmission path selecting signal to thereby adjust a delay timing of a data signal.

Japanese Unexamined Patent Application Publication No. 2007-12245 discloses a device in which an ODT (On-Die termination) operation timing of a memory device is adjusted depending on whether the memory device is located in a first rank or a second rank.

Japanese Unexamined Patent Application Publication No. 2009-217344 discloses a system in which a timing adjusting data used for adjusting a timing of a data signal and a strobe signal is memorized in a delay adjusting memory. A timing of reading out the data is selected and determined by changing the timing of reading out the timing adjusting data.

The present inventor has found problems in those related arts as described below. In the memory system including a related memory controller, a common strobe signal specifying the write/read timing is shared by the plurality of ranks. However, in recent years, the data transmission speed of the memory controller for controlling the memory in a unit of rank has been increasing. A delay variation between the ranks, which has not been considered up to now inhibits high speed data transmission. The problem will be explained referring to FIGS. 1 and 2. FIGS. 1 and 2 are timing charts showing an input point in the memory element.

Referring to FIG. 1, when the data transmission speed is low, each rank satisfies SETUP/HOLD only by adjusting the common strobe signal shared by the ranks. That is, in the related art, because a data fixing time is sufficiently longer than a delay variation between the ranks, the delay variation between the ranks causes no problem.

However, as shown in FIG. 2, when the data transmission speed is high, each rank cannot satisfy SETUP/HOLD only by adjusting the common strobe signal shared by the ranks. When the data fixing time in each rank becomes shorter, the delay variation between the ranks inhibits high speed data transmission.

As described above, Japanese Unexamined Patent Application Publication No. 2003-60488 discloses a circuit in which a timing of data transmission between the memory controller and the memory element can be adjusted. However, in Japanese Unexamined Patent Application Publication No. 2003-60488, the delay variation of the data signal between ranks is not considered, so that each rank cannot satisfy SETUP/HOLD at high speed data transmission. Therefore, in the circuit disclosed in Japanese Unexamined Patent Application Publication No. 2003-60488, high-speed memory access cannot be realized while keeping the data reliability.

Further, in Japanese Unexamined Patent Application Publication No. 2003-60488, only timing of a transmission from the memory controller to the memory element, which is a data transmission timing of a write operation, is adjusted. Therefore, in Japanese Unexamined Patent Application Publication No. 2003-60488, a function of adjusting the data signal is not provided for a read operation, with the result that high-speed data transmission cannot be realized in a read operation.

Further, in Japanese Unexamined Patent Application Publication Nos. 2007-12245 and 2009-217344, the delay variation in the data signal between the ranks is not considered.

### SUMMARY

An exemplary object of the invention is to provide a memory controller, a memory system including the same, and a control method of a memory device that achieve speed-up memory access while keeping the data reliability.

A first exemplary aspect of the present invention is a memory controller which controls a memory device including two or more memory access units, the memory access unit being a write/read access unit including a plurality of memory elements. The memory controller includes: a data control circuit that receives and transmits write/read data from and to an upper level device and generates a write strobe signal; and an adjusting circuit that performs at least one of a first processing and a second processing. In the first processing, a timing of the write strobe signal generated by the data control circuit in a write operation is adjusted for each memory access unit and a write strobe adjusting signal specifying a timing for each memory access unit to load write data is generated. In the second processing, a timing of the read strobe signal generated by the memory device in a read operation is adjusted for each memory access unit and a read strobe adjusting signal specifying a timing for the data control unit to read read data from each memory access unit is generated.

A second exemplary aspect of the present invention is a control method of a memory device receiving and transmitting write/read data from and to an upper level device and generating a write strobe signal. The control method performs at least one of a first processing and a second processing. In the first processing, a timing of the write strobe signal generated by a data control circuit in a write operation is adjusted for each memory access unit and a write strobe adjusting signal specifying a timing for each memory access unit to load write data is generated. In the second processing, a timing of the read strobe signal generated by the memory device in a read operation is adjusted for each memory access unit and a read strobe adjusting signal specifying a timing for the data control unit to read data read out from each memory access unit is generated.

### BRIEF DESCRIPTION OF THE DRAWINGS

The above and other aspects, features, and advantages of the present invention will become more apparent from the following description of certain exemplary embodiments when taken in conjunction with the accompanying drawings, in which:

FIG. 1 is a timing chart showing input points in a memory element at low data transmission speed in a related art;

FIG. 2 is a timing chart showing the input points in the memory element at high data transmission speed in a related art;

FIG. 3 is a schematic block diagram showing a memory controller according to the present invention;

FIG. 4 is a timing chart showing input points in a memory element at low data transmission speed in a memory system including a memory controller according to a first exemplary embodiment of the present invention;

FIG. 5 is a schematic block diagram showing a memory system including the memory controller according to the first exemplary embodiment of the present invention;

FIG. 6 is a diagram showing a configuration of an adjusting circuit of the memory controller according to the first embodiment of the present invention; and

FIG. 7 is a block diagram showing a memory system including a memory controller according to a second exemplary embodiment of the present invention.

### EXEMPLARY EMBODIMENTS

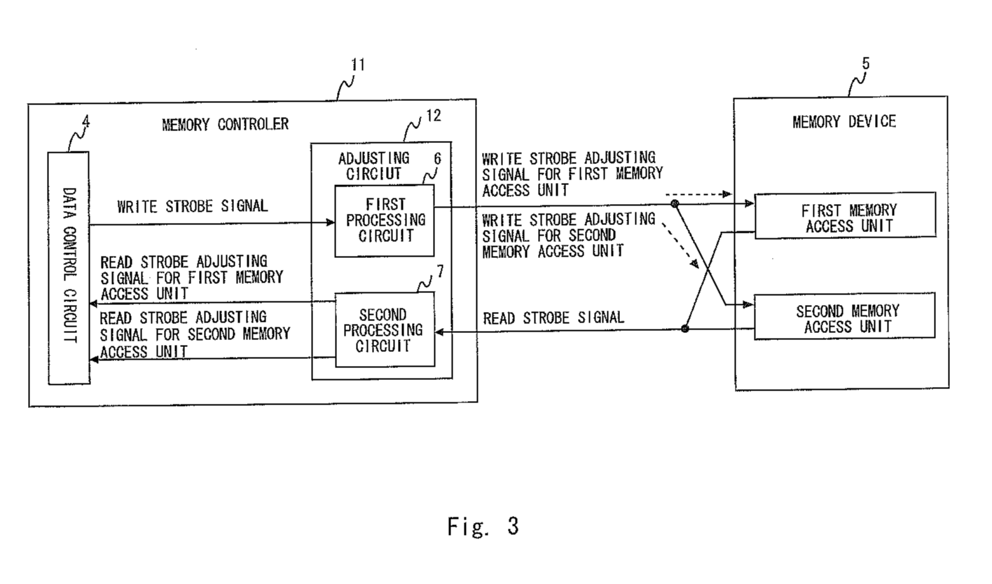

Hereinafter, referring to the drawings, preferable embodiments of the present invention will be described. Before a memory controller according to each embodiment is explained, a schema of the memory controller in the present invention will be described. FIG. 3 is a schematic block diagram showing a memory controller according to the present invention. A memory controller 11 is a device that relays data between a higher level device (not shown) and a memory device 5. The memory controller 11 may be installed in the higher level device like a CPU (Central Processing Unit) or the like. The memory controller 11 may be also installed in the memory device 5.

On aspect of the present invention is that a write/read strobe signal specifying a timing of write/read operation is adjusted for each memory access unit. Write/read data is also received and transmitted between the memory controller 11 and the memory device 5, in addition to the strobe signal. However, the write/read data is omitted in FIG. 3 for illustrative purposes.

The memory device 5 which is an object controlled by the memory controller 11 is configured with two or more memory access units. One memory access unit includes a plurality of memory elements. The memory controller 11 controls the write/read operation for each write/read access unit. The write/read operation is executed for the memory device 5 in response to a request from the higher level device. The write/read access unit may be configured as a rank of the memory device 5.

The memory controller 11 includes a data control circuit 4 and an adjusting circuit 12. The data control circuit 4 receives and transmits the write/read data with the higher level device. The data control circuit 4 generates a write strobe signal. The write strobe signal specifies a timing of loading the write data received from the higher level device in the memory device 5. The write strobe signal generated in the data control circuit 4 is transmitted to the adjusting circuit 12. The data control circuit 4 loads read data read out from the memory device 5 at a timing specified by a read strobe signal generated in the memory device 5.

The adjusting circuit 12 includes at least one of a first processing circuit 6 used in the write operation and a second processing circuit 7 used in the read operation. Both of the first processing circuit 6 and the second processing circuit 7 are illustrated in FIG. 3 for illustrative purposes. However, the invention is not limited to the illustration. The adjusting circuit 12 according to the present invention may include only one of the first processing circuit 6 and the second processing circuit 7.

The first processing circuit 6 adjusts a timing of a write strobe signal respect to the memory access unit. The write strobe signal is generated by the data control circuit 4 in the write operation. The first processing circuit 6 adjusts a delay in a received write strobe signal to generate a first memory access unit write strobe signal specifying a timing of loading the write data in the first memory access unit. Further, the first processing circuit 6 adjusts a delay in the received write strobe signal to generate a second memory access unit write strobe signal specifying a timing of loading the write data in the second memory access unit. Note, the write strobe signal before being adjusted by the first processing circuit 6 is called “the write strobe signal” in this explanation. The write strobe signal after being adjusted by the first processing circuit 6 is called “the write strobe adjusting signal” in this explanation.

The first write strobe adjusting signal generated by the first processing circuit 6 is supplied to the first memory access unit activated by not shown a control signal (chip select). In the same way, the second write strobe adjusting signal generated by the first processing circuit 6 is supplied to the second memory access unit activated by the control signal (chip select).

In the first memory access unit, the write data received from the upper level device is loaded at a timing of an edge of received first write strobe adjusting signal. In the same way, in the second memory access unit, the write data received from the upper level device is loaded at a timing of an edge of received second write strobe adjusting signal.

The second processing circuit 7 receives a read strobe signal generated by the memory device 5 in the read operation. The second processing circuit 7 adjusts a timing of the read strobe signal for each memory access unit, and transmits it to the data control circuit 4. Specifically, the second processing circuit 7 generates a first memory access unit read strobe signal specifying a timing of reading out the read data in the first memory access unit. Further, the second processing circuit 7 generates a second memory access unit read strobe signal specifying a timing of reading out the read data in the second memory access unit. Note, the read strobe signal before being adjusted by the second processing circuit 7 is herein referred to as a “read strobe signal”. The read strobe signal adjusted by the first processing circuit 7 is herein referred to as a “read strobe adjusting signal”.

The write/read strobe signal may be synchronized with a clock received for each memory access unit to adjust the write/read strobe signal in the first processing circuit 6 and the second processing circuit 7.

The data control circuit 4 loads the read data read out from the first memory access unit at a timing of an edge of a first read strobe adjusting signal received from an adjusting circuit 2. The data control circuit 4 loads the read data read out from the second memory access unit at a timing of an edge of a second read strobe adjusting signal received from the adjusting circuit 2.

In this way, the memory controller according to the present invention adjusts the timing of the write/read strobe signal each write/read access unit, and generates the write/read strobe adjusting signal for each write/read access unit. Therefore, the delay variation of data signals between the ranks can be reduced, thereby improving the processing speed of the write/read processing.

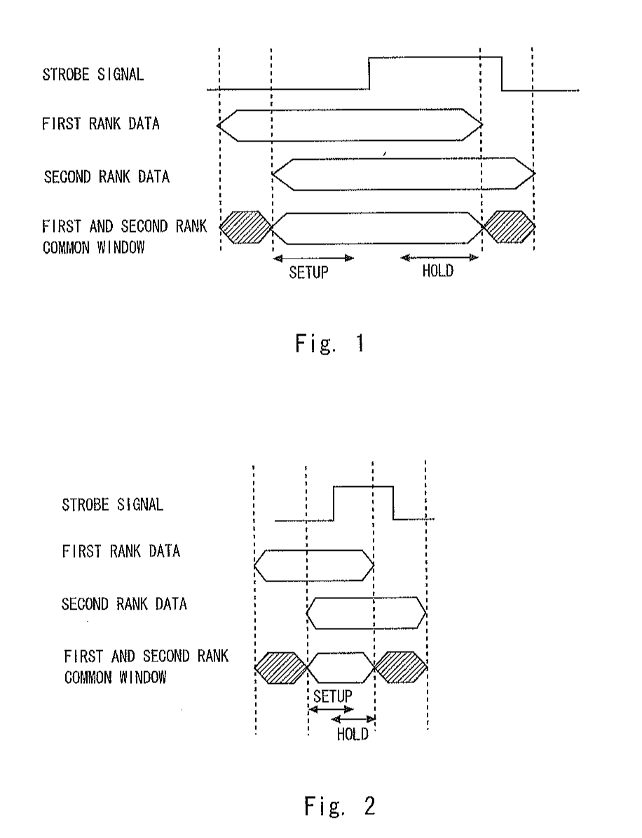

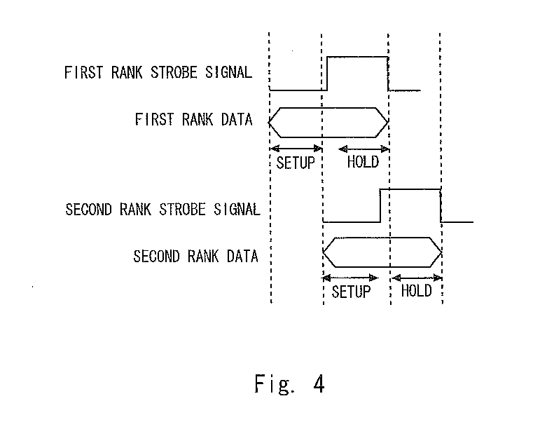

Referring to FIGS. 2 and 4, advantages of the present invention will be explained in detail. FIG. 4 is a timing chart of an input point in a memory element at low data transmssion speed in a memory system including the memory controller according to the first embodiment of the present invention. In the related art, as shown in FIG. 2, a common (write/read) strobe signal is shared by the first and second ranks. Therefore, as shown in FIG. 2, a rising edge of a strobe signal specifying a timing of loading data needs to be located in a period when both of first rank data and second rank data are fixed. That is, the rising edge of the strobe signal needs to be located in a window common to the first and second ranks. However, under high-speed data transmission, a period in which data is fixed in each rank is not enough for obtaining enough SETUP/HOLD time. This causes a problem that the reliability of wrote/read data becomes worse.

As shown in FIG. 4, in the memory controller 11 according to the present invention, it is only necessary to adjust the edge timing of the (write/read) strobe adjusting signal for each of the first and the second ranks while considering a period when the rank data is fixed in own rank. Therefore, the strobe adjusting signal can be adjusted to an optimal timing for obtaining enough SETUP/HOLD time in each rank. Consequently, even though a transmission data rate is high, the reliability of data memorized in the memory device 5 and the read data can be maintained.

The memory controller 11 includes the first processing circuit 6 for adjusting the delay of the write strobe signal in the write operation, and the second processing circuit 7 for adjusting the delay of the read strobe signal in the read operation. Therefore, in both of the write and read operations, high-speed memory access can be realized while maintaining the data reliability.

### First Exemplary Embodiment

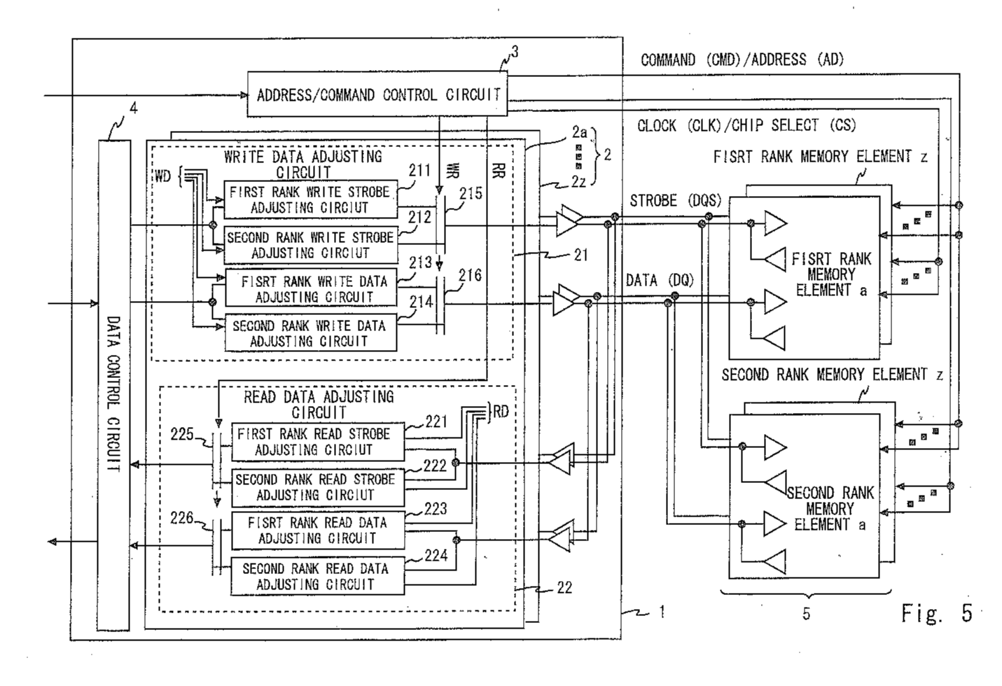

A memory controller according to a first embodiment of the present invention will be described. FIG. 5 is a schematic block diagram showing a memory system including the memory controller according to the first embodiment of the present invention. Note, the data control circuit 4, the first processing circuit 6, the second processing circuit 7, the first memory access unit, and the second memory access unit shown in FIG. 3 respectively correspond to the data control circuit 4, a write data adjusting circuit 21, a read data adjusting circuit 22, a first rank, and a second rank shown in FIG. 5. In the first embodiment, the adjusting circuit 2 includes a plurality of adjusting circuits 2a to 2z. The adjusting circuits 2a to 2z are shared by respective memory elements a to z in each rank. In each of the adjusting circuits 2a to 2z, each timing of the write/read strobe signals is adjusted and a timing of write/read data is adjusted for each of the memory elements a to z.

The memory device 5 which is an object to be controlled by the memory controller 1 is connected to two ranks, the first and second ranks. Each of the first and second ranks includes the plurality of memory elements a to z.

The memory controller 1 includes the data control circuit 4, the adjusting circuit 2, and an address/command control circuit 3. As described above, the data control circuit 4 receives the write data from the upper level device and transmits the read data read out from the memory device 5 to the upper level device. A transmission path for transmitting a command (CMD)/address (AD) signal generated in response to a write/read request from the upper level device is connected to all the memory elements a to z in the first and second ranks. The command (CMD)/address (AD) signal is supplied to all the memory elements a to z by the address/command control circuit 3.

A transmission path for transmitting a clock (CLK)/chip select (CS) signal is connected to the memory elements a to z in each rank. The clock (CLK)/chip select (CS) signal is transmitted from the address/command control circuit 3 for each rank unit. A strobe signal (DQS) and a data signal (DQ) are bidirectional signals. A transmission path for transmitting the strobe signal (DQS) and the data signal (DQ) is connected to the memory elements a to z in each rank with wires and also connected to the memory controller 1. While the above explanation says that the strobe signal adjusted by the adjusting circuit 2 is referred to as a “strobe adjusting signal”. But the strobe signal (DQS) and the data signal (DQ) shown in FIG. 5 include the strobe signals and data signals obtained before and after adjustment by the adjusting circuit 2.

Upon receiving the write request or the read request issued by the upper level device, the address/command control circuit 3 issues a write command or a read command and an address to the memory elements a to z. Further, the address/command control circuit 3 issues the chip select (CS) to the rank to be accessed.

The data control circuit 4 receives the write data from the upper level device in the write operation and issues the write data to the adjusting circuit 2. In the read operation, the data control circuit 4 loads the read data of the rank unit at the edge timing of the first read strobe adjusting signal or the second read strobe adjusting signal, and transmits the loaded read data to the upper level device. The first read strobe adjusting signal and the second read strobe adjusting signal are issued by the adjusting circuit 2 and adjusted in the rank unit.

The adjusting circuit 2 includes the adjusting circuits 2a to 2z which are provided to respectively correspond to the memory elements a to z. The adjusting circuits 2a to 2z are shared by the first rank and the second rank. Specifically, the adjusting circuit 2a is shared by the memory element a in the first rank and the memory element a in the second rank. In the same way, the adjusting circuit 2z is shared by the memory element z in the first rank and the memory element z in the second rank. Each of the adjusting circuits 2a to 2z includes the write data adjusting circuit 21 and the read data adjusting circuit 22.

In the write operation, the write data adjusting circuit 21 adjusts timings of the write data (DQ) and the write strobe signal (DQS) which are transmitted from the data control circuit 4 to the memory device 5, and transmits the adjusted write data (DQ) and the write strobe signal (DQS) to each of the memory elements a to z in the memory device 5. The write data adjusting circuit 21 includes a first rank write strobe adjusting circuit 211, a second rank write strobe adjusting circuit 212, a first rank write data adjusting circuit 213, a second rank write data adjusting circuit 214 and selectors 215 and 216.

The first rank write strobe adjusting circuit 211 adjusts a delay of the write strobe signal generated by the data control circuit 4 to an optimal timing for the memory elements a to z of the first rank to load the write data. The first rank write strobe adjusting circuit 211 receives a write delay adjusting signal WD1 set to a delay value with which the memory elements a to z in the first rank can load the write data. The first rank write strobe adjusting circuit 211 transmits a signal adjusted according to the write delay adjusting signal WD1 as the first write strobe adjusting signal to the selector 215. The first write strobe adjusting signals generated by the first rank write strobe adjusting circuits 211 in the adjusting circuits 2a to 2z are adjusted to a common timing. That is, the write delay adjusting signal WD1 is commonly input to the first rank write strobe adjusting circuits 211 in the adjusting circuits 2a to 2z.

The second rank write strobe adjusting circuit 212 adjusts the write strobe signal generated by the data control circuit 4 to an optimal timing for the memory elements a to z in the second rank to load the write data. The second rank write strobe adjusting circuit 212 receives a write delay adjusting signal WD2 set to a delay value with which the memory elements a to z in the second rank can load the write data. The second rank write strobe adjusting circuit 212 transmits a signal adjusted according to the write delay adjusting signal WD2 as the second write strobe adjusting signal to the selector 215. The second write strobe adjusting signals generated by the second rank write strobe adjusting circuits 212 in the adjusting circuits 2a to 2z are adjusted to a common timing. That is, the write delay adjusting signal WD2 is commonly input to the second rank write strobe adjusting circuits 212 in the adjusting circuits 2a to 2z.

The selector 215 receives the first rank write strobe adjusting signal generated by the first rank write strobe adjusting circuit 211 and the second rank write strobe adjusting signal generated by the second rank write strobe adjusting circuit 212. The selector 215 selects the first write strobe adjusting signal or the second write strobe adjusting signal according to a write rank activate signal WR received from the address/command control circuit 3 and transmits the selected signal as the strobe signal (DQS) to the memory device 5. Note, the write rank activate signal WR is a signal specifying one of the first rank and the second rank to be activated by the chip select (CS) in the write operation.

The first rank write data adjusting circuit 213 adjusts a delay of the write data signal received from the data control circuit 4 to an optimal timing for writing the write data to the memory elements a to z in the first rank. The first rank write data adjusting circuit 213 receives a write delay adjusting signal WD3 set to a delay value with which each of the memory elements a to z in the first rank can load the write data. The first rank write data adjusting circuit 213 transmits a signal adjusted by the write delay adjusting signal WD3 as the first rank write data adjusting signals a to z to the memory elements a to z.

The write delay adjusting signal WD3 is a signal for setting a delay time of the write data signal to a write enable time. The write delay adjusting signal WD3 is set so that the write data signal has an appropriate delay time. Specifically, after writing predetermined data into the memory element, it is judged whether data returned from the memory element matches the written predetermined data or not, thereby setting the write delay adjusting signal WD3. The first rank write data adjusting signals a to z are respectively set for the memory elements a to z and adjusted to the optimal timing for writing in each of the memory elements a to z. That is, the write delay adjusting signal WD3 received to the first rank write data adjusting circuits 213 in each of the adjusting circuits 2a to 2z is set to different values depending on the each memory elements a to z.

The second rank write data adjusting circuit 214 adjusts the delay of the write data signal received from the data control circuit 4 to an optimal timing for writing the write data into the memory elements a to z in the second rank. The second rank write data adjusting circuit 214 receives a write delay adjusting signal WD4 set to a delay value with which each of the memory elements a to z in the second rank can load the write data. Note, the write delay adjusting signal WD4 is set in the same way of the write delay adjusting signal WD3. The second rank write data adjusting circuit 214 transmits the second rank write data adjusting signals a to z adjusted by the delay adjusting signal WD4 to each of the memory elements a to z. The second rank write data adjusting signals a to z generated by the second rank write data adjusting circuit 214 in each of the adjusting circuits 2a to 2z are respectively set for the memory elements a to z. The second rank write data adjusting signals a to z are adjusted for each memory elements a to z to an optimal timing in which write operation can be performed in each of the memory elements a to z. That is, the write delay adjusting signal WD4 received by the second rank write data adjusting circuit 214 in each of the adjusting circuits 2a to 2z is set to different values depending on the memory elements a to z.

The selector 216 receives the first rank write data adjusting signal generated by the first rank write data adjusting circuit 213 and the second rank write data adjusting signal generated by the second rank write data adjusting circuit 214. The selector 216 selects the first rank write data adjusting signal or the second rank write adjusting signal according to the write rank activate signal WR and transmits the selected signal to the memory device 5.

The read data adjusting circuit 22 includes a first rank read strobe adjusting circuit 221, a second rank read strobe adjusting circuit 222, a first rank read data adjusting circuit 223, a second rank read data adjusting circuit 224, and selectors 225 and 226.

The first rank read strobe adjusting circuit 221 adjusts a delay of the read strobe signal generated by the memory device 5 to an optimal timing for the data control circuit 4 to read out the read data from the first rank. The first rank read strobe adjusting circuit 221 receives a read delay adjusting signal RD1 set to a delay value with which the data control circuit 4 can load the read data read out from the first rank. The first rank read strobe adjusting circuit 221 transmits a signal adjusted by the read delay adjusting signal RD1 as the first rank read strobe adjusting signal to the selector 225. Note, the first rank read strobe adjusting signal generated by the first rank read strobe adjusting circuit 221 is adjusted to common timing in the memory elements a to z in the first rank. That is, the read delay adjusting signal RD1 is commonly input to the first rank read strobe adjusting circuits 221 in each adjusting circuits 2a to 2z.

The second rank read strobe adjusting circuit 222 adjusts a delay of the read strobe signal generated by the memory device 5 to an optimal timing for the data control circuit 4 to read out the read data from the second rank. The second rank read strobe adjusting circuit 222 receives a read delay adjusting signal RD2 set to a delay value with which the data control circuit 4 can load the read data read out from the second rank. The second rank read strobe adjusting circuit 222 transmits a signal adjusted by the read delay adjusting signal RD2 as the second rank read strobe adjusting signal to the selector 225. Note, the second rank read strobe adjusting signal generated by the first rank read strobe adjusting circuit 222 is adjusted to a common timing in the memory elements a to z in the second rank. That is, the read delay adjusting signal RD2 is commonly input to the second rank read strobe adjusting circuits 222 in the adjusting circuits 2a to 2z.

The selector 225 receives the first rank read strobe adjusting signal generated by the first rank read strobe adjusting circuit 221 and the second rank read strobe adjusting signal generated by the second rank read strobe adjusting circuit 222. The selector 225 transmits the first rank read strobe adjusting signal or the second rank read strobe adjusting signal according to a read rank activate signal RR received from the address/command control circuit 3 to the data control circuit 4. Note, the read rank activate signal RR is a signal specifying one of the first rank and second rank to be activated by the chip select (CS) in the read operation.

The read data signal (DQ) issued by the memory elements a to z is distributed to the adjusting circuit 2 which is arranged to each rank unit. The adjusting circuit includes the first rank read data adjusting circuit 223 and the second rank read data adjusting circuit 224. The first rank read data adjusting circuit 223 and the second rank read data adjusting circuit 224 adjust a delay of the read data signal (DQ) according to read data adjusting signals RD3 and RD4. In the same way as the write delay adjusting signals WD3 and WD4, the read delay adjusting signals RD3 and RD4 are set as signals capable of adjusting a timing of the read data signal (DQ) optimally by comparing an input value and an expected value.

The first rank read data adjusting circuit 223 adjusts a delay of the read data received from the memory device 5 to an optimal timing for the data control circuit 4 to read out the read data. The first rank read data adjusting circuit 223 transmits the adjusted signals as second read data adjusting signals a to z to the data control circuit 4. The first read data adjusting signals a to z are respectively set for the memory elements a to z and adjusts to optimal timings in which read operation can be performed in each of the memory elements a to z. That is, the read delay adjusting signals RD3 received by the first rank read data adjusting circuits 223 of the adjusting circuits 2a to 2z are set to different values depending on the memory elements a to z.

The second rank read adjusting circuit 224 adjusts a delay of the read data signal received from the memory device 5 to an optimal timing for the data control circuit 4 to read out the read data. The second rank read data adjusting circuit 224 transmits the adjusted signals as the second read data adjusting signals a to z to the data control circuit 4. The second read data adjusting signals a to z are respectively set for the memory elements a to z and adjusts to optimal timings in which read operation can be performed in each of the memory elements a to z. That is, the read adjusting signals RD4 received by the second rank read data adjusting circuits 224 of each of the adjusting circuits 2a to 2z is set to different values depending on the memory elements a to z.

The selector 226 receives the first read data adjusting signal generated by the first rank read data adjusting circuit 223 and the second rank read data adjusting signal generated by the second rank read data adjusting circuit 224. The selector 226 transmits the first read data adjusting signal or the second read data adjusting signal to the data control circuit 4 according to a read rank activate signal RR received from the address/command control circuit 3.

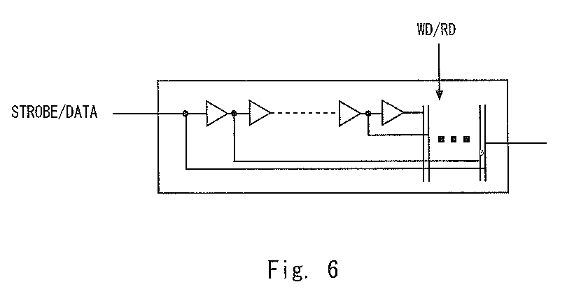

Next, an exemplary configuration of the adjusting circuit 2 will be described. FIG. 6 is a diagram showing an exemplary configuration of the adjusting circuit 2 of the memory controller 1 according to the first embodiment of the present invention. As shown in FIG. 6, the adjusting circuit 2 has a plurality of delay gates connected in series. A plurality of signal lines are connected between the delay gates and signals of the plurality of the signal lines are received by the selector. An output of each adjusting circuit, that is, a delay value, is determined depending on the number of steps of the delay gate selected by select signals. The select signals includes the write delay adjusting signals WD1 to WD4 and the read delay adjusting signals RD1 to RD4. The components of the adjusting circuit 2 are not limited to those described above, and any configuration can be applied.

Hereinafter, operations of the memory controller 1 configured as described above and a memory system including the same will be explained.

### [Write Operation]

Referring to FIG. 5, the write operation of the memory controller 1 according to the first embodiment of the present invention and the memory system including to the same will be described. When the upper level device issues the write request and the write data for the first rank to the memory controller 1, the address/command control circuit 3 issues the chip select signal (CS), a write command, and an address for each of the memory elements a to z in the first rank. In a general memory element such as a DDR-SDRAM (Double-Data-Rate Synchronous Dynamic Random Access Memory), the write data may be issued after a lapse of a sufficient time since the issuance of the write command. That is, the data control circuit 4 may transmit the strobe signal and the write data to the delay adjusting circuits 2a to 2z after a lapse of sufficient time to satisfy the specifications of the memory element.

The address/command control circuit 3 issues the write rank activate signal WR to the adjusting circuits 2a to 2z at this timing. In the case where the write operation is performed on the first rank, the address/command control circuit 3 issues the write rank activate signal WR to the selectors 215 and 216 in the write data adjusting circuit 21 so that the adjusting circuits (the first rank write strobe adjusting circuit 211 and the first rank write data adjusting circuit 213) on the first rank side are selected.

In this way, the first rank write strobe adjusting signal (DQS) is transmitted from the selector 215 to the memory elements a to z in the first rank. On the other hand, the first rank write data adjusting signal (DQ) is transmitted from the selector 216 to the memory elements a to z in the first rank. At the time, the write delay adjusting signals WR1 and WR3 received by the first rank write strobe adjusting circuit 211 and the first rank write data adjusting circuit 213 are set for the memory elements a to z in the first rank to write the data.

The memory elements a to z of the first rank load the first rank write data adjusting signal (DQ) at the edge timing of the first rank write strobe adjusting signal (DQS) received from the adjusting circuit 2. The delay of the first rank write data adjusting signal (DQ) is adjusted.

On the other hand, in the case where the write operation is performed on the second rank, the address/command control circuit 3 issues the write rank activate signal WR to the selectors 215 and 216 in the write data adjusting circuit 21 so that the adjusting circuits (the second rank write strobe adjusting circuit 212 and the second rank write data adjusting circuit 214) on the second rank side are selected.

In this way, the second rank write strobe adjusting signal (DQS) is transmitted from the selector 215 to the memory elements a to z in the second rank. On the other hand, the second rank write data adjusting signal (DQ) is transmitted from the selector 216 to the memory elements a to z in the second rank. At the time, the write delay adjusting signals WR2 and WR4 received by the second rank write strobe adjusting circuit 212 and the second rank write data adjusting circuit 214 are set for the memory elements a to z in the second rank to write the data.

The memory elements a to z of the second rank load the second rank write data adjusting signal (DQ) at the edge timing of the second rank write strobe adjusting signal (DQS) received from the adjusting circuit 2. The delay of the second rank write data adjusting signal (DQ) is adjusted.

In this way, in the memory device 5, the first rank can load the write data at the optimal timing for the first rank and the second rank can load the write data at the optimal timing of the second rank.

### [Read Operation]

The read operation of the memory controller 1 according to the first embodiment of the present invention and the memory system including to the same will be described. When the upper level device issues the read request for the first rank to the memory controller 1, the address/command control circuit 3 issues the chip select signal (CS), a read command, and an address to the memory elements a to z in the first rank. In a general memory element such as a DDR-SDRAM, the read data is issued after a lapse of a sufficient time since the issuance of the read command. Therefore, the address/command control circuit 3 may issue the read rank activate signal RR to the adjusting circuits 2a to 2z at this timing.

In the case where the read operation is performed on the first rank, the address/command control circuit 3 issues the read rank activate signal RR to the selectors 225 and 226 in the read data adjusting circuit 22 so that the adjusting circuits (the first rank read strobe adjusting circuit 221 and the first rank read data adjusting circuit 223) on the first rank side are selected. Therefore, the first rank read strobe adjusting signal (DQS) is transmitted from the selector 225 to the data control circuit 4. On the other hand, the first rank read data adjusting signal (DQ) is transmitted from the selector 226 to the data control circuit 4. At the time, the read delay adjusting signals RD1 and RD3 received by the first rank read strobe adjusting circuit 221 and the first rank read data adjusting circuit 223 are set for the data control circuit 4 to read the read data from the memory elements a to z in the first rank.

In the case where the read operation is performed on the second rank, the address/command control circuit 3 issues the read rank activate signal RR to the selectors 225 and 226 in the read data adjusting circuit 22 so that the adjusting circuits (the second rank read strobe adjusting circuit 222 and the second rank read data adjusting circuit 224) on the second rank side are selected. Therefore, the second rank read strobe adjusting signal (DQS) is transmitted from the selector 225 to the data control circuit 4. On the other hand, the second rank read data adjusting signal (DQ) is transmitted from the selector 226 to the data control circuit 4. At the time, the read delay adjusting signals RD2 and RD4 received by the second rank read strobe adjusting circuit 222 and the second rank read data adjusting circuit 224 are set for the data control circuit 4 to read the read data from the memory elements a to z in the second rank.

In the read operation for the first rank, the data control circuit 4 loads the first read data adjusting signal received from the adjusting circuit 2 at a timing specified by the first rank read strobe adjusting signal received from the adjusting circuit 2. In the read operation for the second rank, the data control circuit 4 loads the second read data adjusting signal received from the adjusting circuit 2 at a timing specified by the second rank read strobe adjusting signal received from the adjusting circuit 2.

In this way, the data control circuit 4 can load the read data from the first rank at the optimal timing for the first rank and the read data from the second rank at the optimal timing for the second rank. The data control circuit 4 transmits the data thus loaded from the first rank and the second rank to the upper level device.

As described above, the memory controller 1 according to the first exemplary embodiment includes the adjusting circuits 211 to 214 and 221 to 224 which are provided for each rank. Therefore, although the data transmission speed in the memory interface has been increasing year by year, the influence of the delay variation between the ranks can be decreased, thereby realizing high-speed data transmission. Specifically, as shown in FIG. 4, the edge timings of the strobe adjusting signal can be adjusted for each rank in consideration of the period in which own rank data is fixed. This makes it possible to adjust the strobe adjusting signal to an optimal timing for each rank to ensure sufficient SETUP/HOLD. Therefore, even with a high data transmission rate, the data reliability of the data memorized in the memory device and the read data can be maintained.

### [Second Exemplary Embodiment]

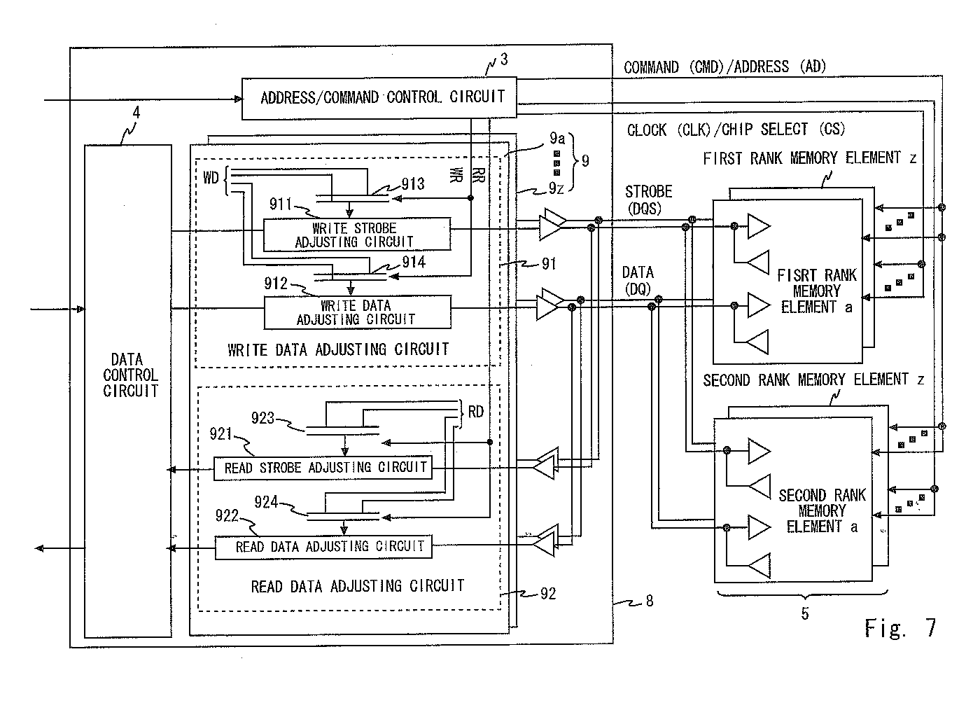

A memory controller according to a second embodiment of the present invention and a memory system including the same will be described. FIG. 7 is a block diagram showing a memory controller 8 according to the second embodiment of the present invention and a memory system including the same. The basic configuration of the second embodiment is the same as that of the first embodiment. In the memory controller 1 according to the first embodiment 1, the write/read strobe signal adjusting circuits and the write/read data signal adjusting circuits for adjusting the strobe signal and the data signal are provided for each rank.

On the other hand, in the memory controller 8 according to the second embodiment, the write/read strobe signal adjusting circuit and the write/read data signal adjusting circuit are shared between two or more ranks. Note, the address/command control circuit 3, the data control circuit 4, and the memory device 5 basically have the same configuration as that of the first embodiment, and the description thereof is omitted by giving the same reference numbers. Assume herein that strobe signal (DQS) and the data signal (DQ) shown in FIG. 7 include strobe signals and data signals obtained before and after adjustment by an adjusting circuit 9.

As shown in FIG. 7, the memory controller 8 according to the present invention includes the adjusting circuit 9. The adjusting circuit 9 includes adjusting circuits 9a to 9z respectively corresponding to the memory elements a to z. The adjusting circuit 9 includes a write data adjusting circuit 91 and a read data adjusting circuit 92. The write data adjusting circuit 91 corresponds to the first processing circuit 6 shown in FIG. 3 and the read data adjusting circuit 92 corresponds to the second processing circuit 7 shown in FIG. 3. The write data adjusting circuit 91 includes a write strobe adjusting circuit 911, a write data adjusting circuit 912, and selectors 913 and 914.

The write strobe adjusting circuit 911 receives the write delay adjusting signal WD1 generated for the first rank and the write delay adjusting signal WD2 generated for the second rank through the selector 913. The selector 913 selects the write delay adjusting signal WD1 generated for the first rank or the write delay adjusting signal WD2 generated for the second rank according to the write rank activate signal WR received from the address/command control circuit 3, and transmits the selected signal to the write strobe adjusting circuit 911.

Upon receiving the write delay adjusting signal WD1 generated for the first rank from the selector 913, the write strobe adjusting circuit 911 adjusts a delay of the strobe signal (DQS) according to the write delay adjusting signal WD1 and transmits first write strobe adjusting signal for the memory elements a to z in the first rank. In the same way, upon receiving the write delay adjusting signal WD2 generated for the second rank from the selector 913; the write strobe adjusting circuit 911 adjusts a delay of the strobe signal (DQS) according to the write delay adjusting signal WD2 and transmits the second write strobe adjusting signal for the memory elements a to z in the second rank. Note, the write delay adjusting signal WD1 is set to a common value for the memory elements a to z in the first rank and the write delay adjusting signal WD2 is set to a common value for the memory elements a to z in the second rank.

The write data adjusting circuit 912 receives the write data to be written to the first rank or the second rank from the data control circuit 4. The write data adjusting circuit 912 receives the write delay adjusting signal WD3 generated for the first rank and the write delay adjusting signal WD4 generated for the second rank through the selector 914. The selector 914 selects the write delay adjusting signal WD3 generated for the first rank or the write delay adjusting signal WD4 generated for the second rank according to the write rank activate signal WR received from the address/command control circuit 3 and transmits the selected signal to the write data adjusting circuit 912. Note, delays of the write delay adjusting signals WD3 and WD4 are set to different optimal values for each of the memory elements a to z in each rank.

The read data adjusting circuit 92 includes a read strobe adjusting circuit 921, a read data adjusting circuit 922, and selectors 923 and 924. The read data adjusting circuit 921 receives the read strobe signal from the memory elements a to z in the first rank or the second rank. The read strobe adjusting circuit 921 receives the read delay adjusting signal RD1 generated for the first rank or the read delay adjusting signal RD2 generated for the second rank through the selector 923. The selector 923 selects the read delay adjusting signal RD1 generated for the first rank or the read delay adjusting signal RD2 generated for the second rank according to the read rank activate signal RR received from the address/command control circuit 3, and transmits the selected signal to the read strobe adjusting circuit 921.

In the same way, the read data adjusting circuit 922 receives the read data signal output from the memory elements a to z in the first rank or the second rank. The read data adjusting circuit 922 receives the read delay adjusting signal RD3 generated for the first rank or the read delay adjusting signal RD4 generated for the second rank through the selector 924. The selector 924 selects the read delay adjusting signal RD3 generated for the first rank or the read delay adjusting signal RD4 generated for the second rank according to the read rank activate signal RR received from the address/command control circuit 3, and transmits the selected signal to the read strobe adjusting circuit 922.

In this way, in the memory controller 8 according to the second embodiment, the adjusting circuits are shared between the ranks. This provides an advantage of reducing the circuit size compared to the first embodiment. Note, as with the first embodiment, the second embodiment also provides advantages of the present invention in that high-speed write/read operations can be realized while keeping the data reliability.

Each of the above-described exemplary embodiments can be combined as desirable by one of ordinary skill in the art.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

As described above, the present invention is explained as a device invention. However, the present invention can be realized as a control method of the memory device. Specifically, the present invention can also be implemented as the control method of the memory device performing write/read operations in a memory access unit including a plurality of memory elements, the control method. The control method includes: receiving and transmitting write/read data from and to an upper level device and generating a write strobe signal and; performing at least one of a first processing and a second processing. In the first processing, a timing of the write strobe signal generated by a data control circuit in a write operation is adjusted for each memory access unit and a write strobe adjusting signal specifying a timing for each memory access unit to load write data is generated. In the second processing, a timing of the read strobe signal generated by the memory device in a read operation is adjusted for each memory access unit and a read strobe adjusting signal specifying a timing for the data control unit to read data read out from each memory access unit is generated.

Further, the above mentioned method can be implemented as a computer program. The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

In the above mentioned first and second exemplary embodiments, the memory device is configured with the first rank and the second rank. However, the present invention is not limited to the above configuration and the memory device may include three or more ranks.

Further, in the above explanation, the write/read strobe adjusting signals are set to different values for rank unit. However, the write/read strobe adjusting signals may be set for each memory element to value optimized for operation in each memory element.

What is claimed is:

1. A memory controller which controls a memory device including two or more memory access units, the memory access unit being a write/read access unit including a plurality of memory elements, comprising:
a data control circuit that receives and transmits write/read data from and to an upper level device and generates a write strobe signal; and
an adjusting circuit that performs at least one of a first processing and a second processing,
wherein in the first processing, a timing of the write strobe signal generated by the data control circuit in a write operation is adjusted for each memory access unit and a write strobe adjusting signal specifying a timing for each memory access unit to load write data is generated, and
in the second processing, a timing of the read strobe signal generated by the memory device in a read operation is adjusted for each memory access unit and a read strobe adjusting signal specifying a timing for the data control unit to read read data from each memory access unit is generated.

2. The memory controller according to claim 1, wherein the adjusting circuit comprises: a write strobe adjusting signal generating circuit of a first memory access unit that adjusts a timing of the write strobe signal to generate a first memory access unit write strobe adjusting signal specifying a timing for the first memory access unit to load the write data; and a write strobe adjusting signal generating circuit of a second memory access unit that adjusts a timing of the write strobe signal to generate a second memory access unit write strobe adjusting signal specifying a timing for the second memory access unit to load the write data.

3. The memory controller according to claim 1, wherein the adjusting circuit comprises: a read strobe adjusting signal generating circuit of a first memory access unit that adjusts a timing of the read strobe signal to generate a first memory access unit read strobe adjusting signal specifying a timing for the data control circuit to read read data from the first access unit; and a read strobe adjusting signal generating circuit of the second memory access unit that adjusts a timing of the read strobe signal to generate a second memory access unit read strobe adjusting signal specifying a timing for the data control circuit to read a read data from the second access unit.

4. The memory controller according to claim 1, wherein the adjusting circuit selectively adjusts the timing of the write strobe signal to one of a first timing and a second timing, supplies a first memory access unit with a first memory access unit write strobe adjusting adjusted to the first timing, and supplies a second memory access unit with a second memory access unit write strobe adjusting signal adjusted to the second timing.

5. The memory controller according to claim 1, wherein the adjusting circuit adjusts the timing of the read strobe signal with a first timing and a second timing selectively, supplies a first memory access unit read strobe adjusting signal adjusted with the first timing to the first memory access unit and supplies a second memory access unit read strobe adjusting signal adjusted with the second timing to the second memory access unit.

6. The memory controller according to claim 1, wherein the adjusting circuit includes a data adjusting signal generating circuit that adjusts a timing of write/read data signals for each memory element.

7. The memory controller according to claim 2, wherein the first memory access unit write strobe signal is generated according to a timing of a clock received by the first memory access unit, and the second memory access unit write strobe signal is generated according to timing of a clock received by the second memory access unit.

8. The memory controller according to claim 1, wherein the first and second memory access units are memory ranks.

9. A memory system comprising a memory device and a memory controller according to claim 1.

10. A control method of a memory device which performs write/read operations in a memory access unit including a plurality of memory elements, the control method comprising:
receiving and transmitting write/read data from and to an upper level device and generating a write strobe signal and;
performing at least one of a first processing and a second processing,
wherein in the first processing, a timing of the write strobe signal generated by a data control circuit in a write operation is adjusted for each memory access unit and a write strobe adjusting signal specifying a timing for each memory access unit to load write data is generated, and
in the second processing, a timing of the read strobe signal generated by the memory device in a read operation is adjusted for each memory access unit and a read strobe adjusting signal specifying a timing for the data control unit to read data read out from each memory access unit is generated.
